(19) United States
(12) Patent Application Publication
(10) Pub. No.: US 2026/0283052 A1
(43) Pub. Date: Sep. 17, 2026

(54) BRIDGE PACKAGE FOR WIRE BONDING IN STACKED SEMICONDUCTOR DEVICES, AND ASSOCIATED SYSTEMS AND METHODS

(71) Applicant: Micron Technology, Inc., Boise, ID (US)

(72) Inventors: Wen Wei Lum, Singapore (SG); Seng Kim Ye, Singapore (SG); Kelvin Tan Aik Boo, Singapore (SG); Hong Wan Ng, Singapore (SG)

(21) Appl. No.: 19/538,897

(22) Filed: Feb. 12, 2026

Related U.S. Application Data
(60) Provisional application No. 63/773,050, filed on Mar. 17, 2025.

(51) Int. Cl. H10W 90/00; H10W 74/10; H10W 90/20

(52) U.S. Cl. CPC H10W 90/724; H10W 74/117; H10W 90/00; H10W 90/297; H10W 90/754

(57) ABSTRACT

Stacked semiconductor devices and associated systems and methods are disclosed herein. A stacked semiconductor device according to the present technology can include a base substrate, a bridge package integrated with the base substrate, and a plurality of dies carried by the base substrate adjacent to the controller die. The bridge package includes an interposer, a controller integrated with a lower surface of the interposer, and a wire bond bridge integrated with an upper surface of the interposer. The controller is coupled to the base substrate and the wire bond bridge via the interposer. The plurality of dies can include a first tier and a second tier carried by the first tier. The first tier includes a plurality of first dies coupled to the active surface via first wire bonds. The second tier includes a plurality of second dies coupled to the wire bond bridge via second wire bonds.

### CROSS-REFERENCE TO RELATED APPLICATIONS

The present application claims priority to U.S. Provisional Patent Application No. 63/773,050, filed Mar. 17, 2025, the disclosure of which is incorporated herein by reference in its entirety.

### TECHNICAL FIELD

The present technology is generally directed to stacked semiconductor devices and more specifically to an elevated redistribution layer interposer for stacked semiconductor devices.

### BACKGROUND

An electronic apparatus (e.g., a processor, a memory device, a memory system, or a combination thereof) can include one or more semiconductor circuits configured to store and/or process information. For example, the apparatus can include a memory device, such as a volatile memory device, a non-volatile memory device, or a combination device. Memory devices, such as dynamic random-access memory (DRAM) and/or high-bandwidth memory (HBM), can utilize electrical energy to store and access data.

With technological advancements in embedded systems and increasing applications, the market is continuously looking for faster, more efficient, and smaller and/or more dense devices. To meet market demands, semiconductor devices are being pushed to the limit with various improvements. Improving devices, generally, may include increasing circuit density, increasing circuit capacity, increasing operating speeds (or otherwise reducing operational latency), increasing reliability, including additional dies in semiconductor packages, reducing power consumption, or reducing manufacturing costs, among other metrics. Attempts, however, to meet market demands, such as by reducing the overall device footprint, can often introduce challenges in other aspects, such as maintaining circuit robustness and/or failure detectability.

### BRIEF DESCRIPTION OF THE DRAWINGS

Many aspects of the present disclosure can be better understood with reference to the following drawings. The components in the drawings are not necessarily to scale. Instead, emphasis is placed on illustrating clearly the principles of the present disclosure. The drawings should not be taken to limit the disclosure to the specific embodiments depicted, but are for explanation and understanding only.

FIG. 1 is a partially schematic cross-sectional view of a stacked semiconductor device with multiple single-tier die stacks.

FIG. 2 is a partially schematic cross-sectional view of a stacked semiconductor device with multi-tiered die stacks.

FIG. 3A is a partially schematic cross-sectional view of a bridge package for a stacked semiconductor device configured in accordance with embodiments of the present technology.

FIG. 3B is a partially schematic cross-sectional view of a stacked semiconductor device configured in accordance with embodiments of the present technology.

FIG. 4 is a flow diagram of a process for manufacturing a stacked semiconductor device in accordance with embodiments of the present technology.

FIG. 5 is a schematic view of a system that includes a semiconductor package configured in accordance with embodiments of the present technology.

### DETAILED DESCRIPTION

As discussed in more detail below, the present disclosure is directed to stacked semiconductor devices that include an interconnection module and/or wing-shaped die stacks, and related systems and methods. For example, a stacked semiconductor device according to the present technology can include a base substrate that has an active surface (e.g., an upper surface, a front surface, and/or the like), as well as a bridge package and a plurality of dies each carried by the active surface. The bridge package can include a base interposer, a controller integrated with a lower surface of the base interposer, and a wire bond bridge integrated with an upper surface of the base interposer opposite the lower surface. The base interposer is integrated with the active surface of the base substrate and carries the controller (e.g., a controller die) above the active surface. The controller is electrically/communicatively coupled to the base substrate and the wire bond bridge via the base interposer (e.g., via one or more metallization layers and bond sites formed in the base interposer). The plurality of dies (e.g., memory dies, such as DRAM dies, NAND dies, and/or the like) can be stacked into multiple-tiered die stacks. Each of the tiers can be staggered (e.g., with each die offset from the die below it) in different directions. For example, a first portion (e.g., a first tier) of a die stack can be staggered in a first direction while a second portion (e.g., a second tier) is staggered in a second direction opposite to the first direction. As a result, the die stack can have a wing-shaped cross-sectional profile.

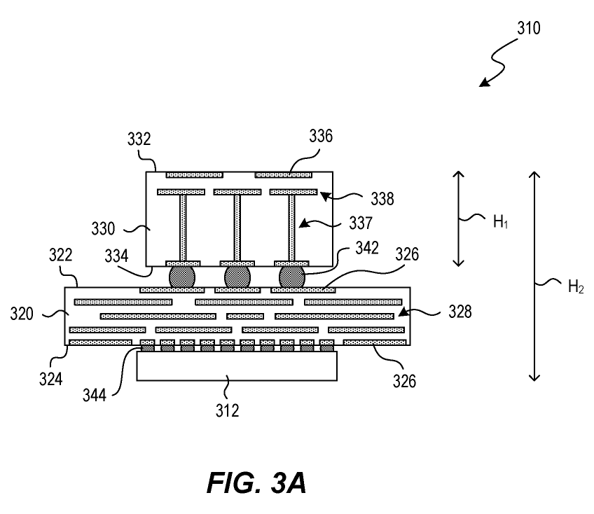

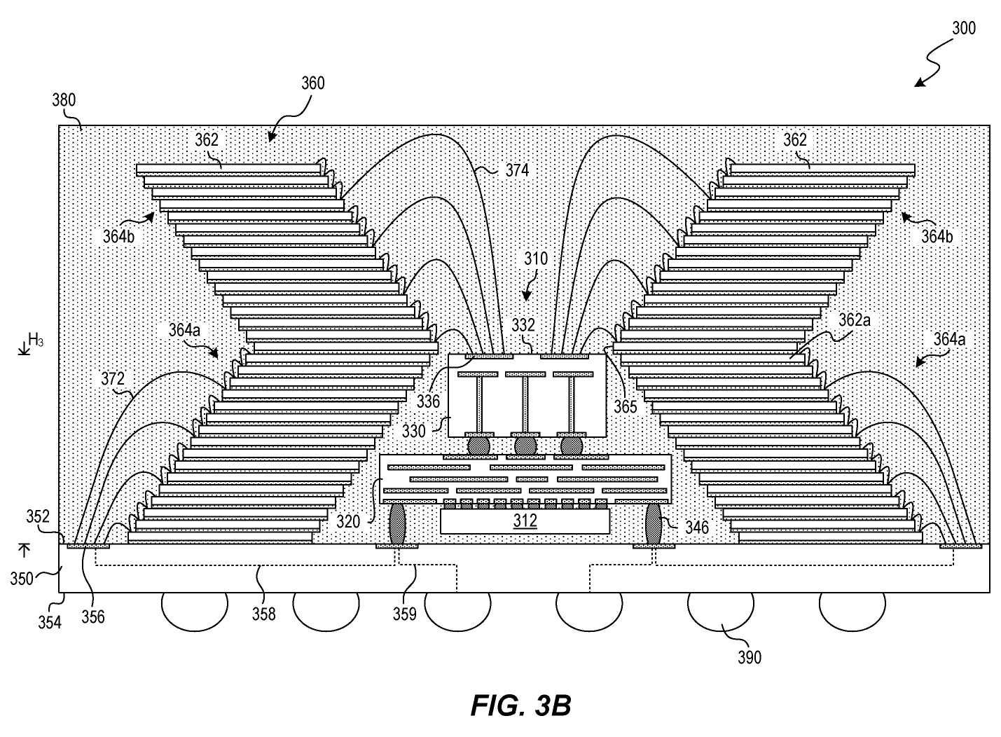

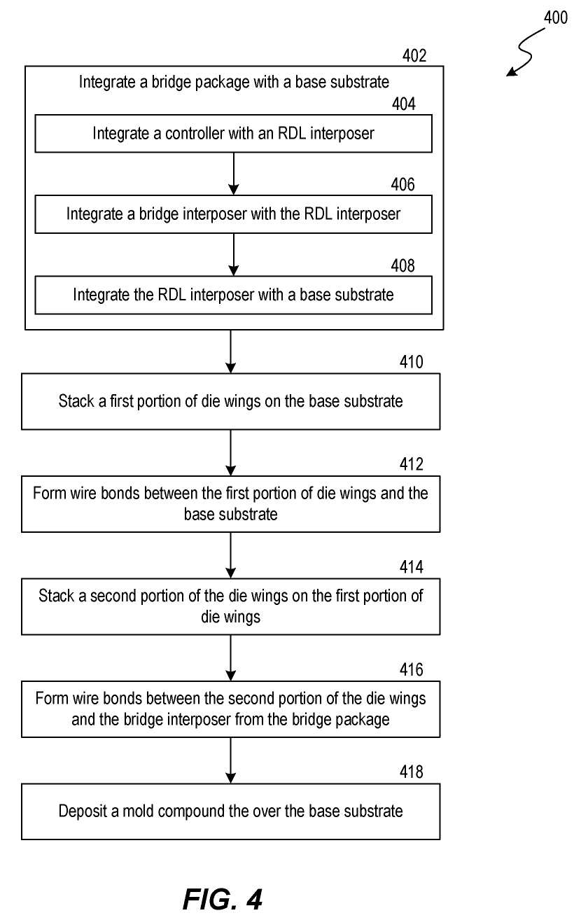

As also discussed in more detail below, the bridge package and the wing-shaped construction of the die stacks can help reduce a wire bond length within the stacked semiconductor device. For example, the interposer substrate can be positioned directly over the controller. Further, the first portion of the die stack can be integrated with the active surface of the base substrate via a first set of wire bonds, while the second portion can be integrated with an upper surface of the interposer substrate. Because the upper surface of the interposer substrate is at an elevation above the active surface, the second set of wire bonds can have a shorter length than if the second set of wire bonds were integrated with the active surface. Additionally, the wing-shaped profile of the die stacks and the position of the interposer substrate allow the first and second sets of wire bonds to be in different locations, thereby helping reduce wire sweep issues for large die stacks (e.g., stacks of more than eight dies). Still further, the interposer substrate (e.g., a redistribution layer (“RDL”) interposer) can provide additional space for route lines for trace matching, thereby creating a three-dimensional (3D) trace-matching scheme for the stacked semiconductor device. As a result of each of the benefits discussed above, the stacked semiconductor packages disclosed herein can help package more dies into a given longitudinal footprint for a semiconductor package. Additional details on the examples of the present technology are discussed below with reference to FIGS. 3A–4.

Although the systems and methods discussed herein are discussed primarily with reference to a shingle-stacked semiconductor device, one of skill in the art will understand that the processes of the present technology discussed herein are not so limited. Purely by way of example, the bridge package and wire bonding schemes of the present technology can be utilized in other semiconductor packages to reduce the length of wire bonds, form a three-dimensional bonding scheme for trace-matching, and/or provide additional solid structures to improve the stability of the semiconductor devices. Additionally, or alternatively, the bridge packages disclosed herein can be used in stacked semiconductor devices with various other die stack configurations. Accordingly, the scope of the invention is not confined to any subset of embodiments, and is confined only by the limitations set out in the appended claims.

As used herein, the terms “vertical,” “lateral,” “upper,” “lower,” “top,” and “bottom” can refer to relative directions or positions of components of the semiconductor devices in view of the orientation shown in the drawings. For example, “bottom” can refer to a feature positioned closer to the bottom of a page than another feature. These terms, however, should be construed broadly to include semiconductor devices, and components thereof, having other orientations, such as inverted or inclined orientations where top/bottom, over/under, above/below, up/down, and left/right can be interchanged depending on the orientation.

The term “semiconductor device or die” generally refers to a solid-state device that includes one or more semiconductor materials. Examples of semiconductor devices include logic devices, memory devices, controllers, or microprocessors (e.g., central processing unit (CPU), graphics processing unit (GPU)), among others. Such semiconductor devices may include integrated circuits or components, data storage elements, processing components, and/or other features manufactured on semiconductor substrates. Further, the term “semiconductor device or die” can refer to a finished device or to an assembly or other structure at various stages of processing before becoming a finished functional device. Depending upon the context in which it is used, the term “substrate” can refer to a wafer-level substrate or to a singulated, die-level substrate. Also, a substrate may include a semiconductor wafer, a package support substrate, an interposer, a semiconductor device or die, or the like. A person having ordinary skill in the relevant art will recognize that suitable steps of the methods described herein can be performed at the wafer level or at the die level.

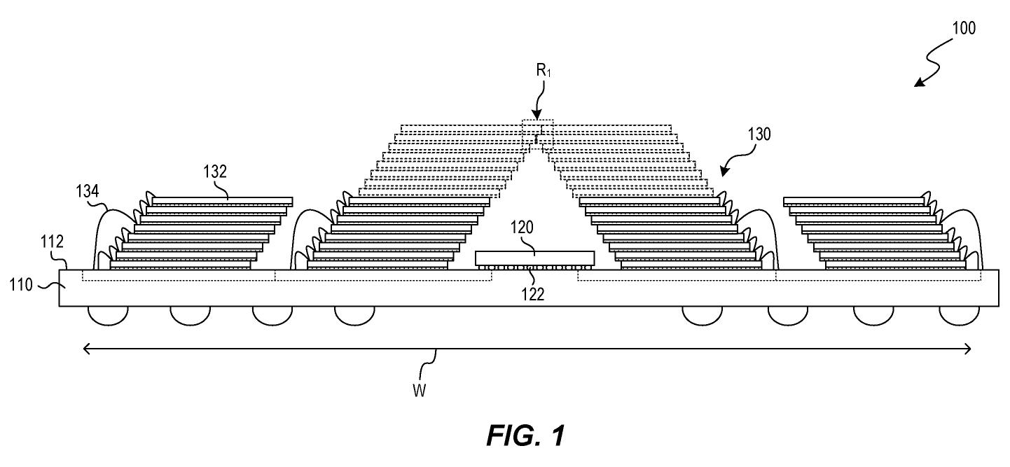

FIG. 1 is a partially schematic cross-sectional view of a stacked semiconductor device 100 with multiple single-tier die stacks. As illustrated in FIG. 1, the stacked semiconductor device 100 (“device 100”) includes a base substrate 110, as well as a controller die 120 and one or more die stacks 130 (four illustrated in FIG. 1) carried by an upper surface 112 of the base substrate 110. The controller die 120 (sometimes also referred to herein as a “controller”) is electrically/communicably and physically coupled to the base substrate 110 via a plurality of conductive structures 122 (e.g., solder structures, conductive pillars, metal-metal bonds, and/or the like). Further, each of the die stacks 130 includes a plurality of dies 132 (e.g., memory dies such as DRAM dies and/or NAND dies, logic dies, processing dies, and/or the like) that are staggered (e.g., stacked in a shingle formation) with respect to each other. As a result, each of the dies 132 can be communicably coupled to the base substrate 110 via one or more wire bonds 134.

In the environment illustrated in FIG. 1, each of the die stacks 130 includes eight of the dies 132 arranged in a single-tier configuration (e.g., a single set of staggered dies with the same offset between each of the dies). As a result, the device 100 includes a total of thirty-two of the dies 132 within a given longitudinal footprint (e.g., within a width W and length (into the page) of the base substrate 110). As industry demands for increased memory and/or increased performance continue, it would be valuable to include additional dies into the device 100. However, as illustrated in region R₁ of FIG. 1, the increase within the illustrated width W is limited before the die stacks 130 run into each other. Accordingly, further increases would require an increase in the width W of the base substrate 110 to provide additional space for the die stacks 130. Said another way, the longitudinal footprint of the base substrate 110 (and therefore the device 100) must increase to meet demands for increased capacity within the device 100. As a result, however, the density of the device (e.g., the memory density) available within a given longitudinal footprint is limited by the eventual overlap in the die stacks 130.

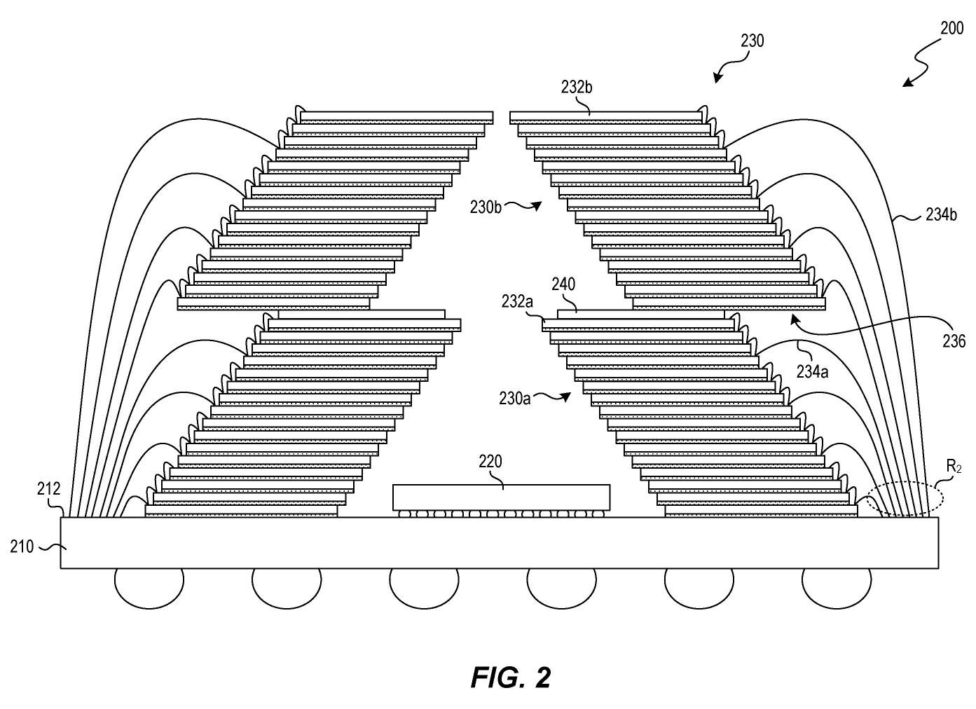

FIG. 2 is a partially schematic cross-sectional view of a stacked semiconductor device 200 with multi-tiered die stacks. As illustrated in FIG. 2, the stacked semiconductor device 200 (“device 200”) is generally similar to the device 100 discussed above with reference to FIG. 1. For example, the device 200 illustrated in FIG. 2 includes a base substrate 210, as well as a controller 220 and one or more die stacks 230 (two illustrated in FIG. 2) integrated with (e.g., carried by and electrically/communicably coupled to) an upper surface 212 of the base substrate 210. In the illustrated embodiment, however, each of the die stacks 230 includes a first tier 230a, a second tier 230b carried by the first tier 230a, and a spacer component 240 positioned between the first tier 230a and the second tier 230b. The first tier 230a (sometimes also referred to herein as a “first portion”) includes a plurality of first dies 232a that are staggered with respect to each other, allowing each of the first dies 232a to be coupled to the base substrate via first wire bonds 234a. Similarly, the second tier 230b (sometimes also referred to herein as a “second portion”) includes a plurality of second dies 232b that are staggered with respect to each other, allowing each of the second dies 232b to be coupled to the base substrate via second wire bonds 234b.

As further illustrated in FIG. 2, the second tier 230b of each of the die stacks 230 is offset from the first tier 230a. The offset allows the die stacks 230 to avoid collision (e.g., as illustrated in the first region R₁ of FIG. 1) while incorporating additional dies into the device 200. As a result, for example, the offset can help the device 200 meet continuing demands to increase overall memory and/or memory within a given longitudinal footprint. The offset, however, results in each of the die stacks 230 including an overhanging portion 236. The overhanging portion 236 creates instability in the die stacks 230 between the first and second tiers 230a, 230b. The instability, in turn, can cause the die stacks 230 to collapse during a stacking process and/or another manufacturing process, thereby reducing throughput and/or increasing the cost of manufacturing. Additionally, or alternatively, the instability provides a weak point in the die stacks 230 that can reduce the lifespan of the device 200.

As further illustrated in FIG. 2, the multi-tiered design of the die stacks 230 requires long wire bonds for the second wire bonds 234b and/or crowing where the first and second wire bonds 234a, 234b are coupled to the base substrate 210. As a result, manufacturing processes for the device 200 often encounter wire-sweep issues in a second region R₂ that undermine (or destroy) the functionality of the device 200.

Stacked semiconductor devices, and associated systems and methods, that address the problems discussed above with reference to FIGS. 1 and 2 are disclosed herein. For example, as discussed in more detail below, stacked semiconductor devices according to the present technology can include multi-tiered die stacks with inverse staggering between tiers, thereby creating wing-shaped die stacks and/or an x-shaped wing for the packages overall. Further, the stacked semiconductor devices disclosed herein can include an elevated redistribution layer (RDL) interposer to help provide a bridge between the upper tier(s) of the die stacks and the base substrate and/or the controller. Additional details on the stacked semiconductor devices, and associated systems and methods, are discussed below with reference to FIGS. 3A–4.

FIG. 3A is a partially schematic cross-sectional view of a bridge package 310 for a stacked semiconductor device configured in accordance with embodiments of the present technology. As illustrated in FIG. 3A, the bridge package 310 can include a controller 312, a base interposer 320, and a wire bond bridge 330. The base interposer 320 (sometimes also referred to herein as a “redistribution layer interposer,” a “redistribution interposer,” a “sub-package interposer,” and/or the like” can have an upper surface 322, a lower surface 324 opposite the upper surface 322, and a variety of metallization features forming electrical connections between the upper surface 322 and the lower surface 324. For example, in the illustrated embodiment, the metallization features include one or more bond sites 326 (sometimes also referred to herein as “interposer bond sites”) at the upper surface 322 and the lower surface 324, as well as a plurality of metallization layers 328 (e.g., route lines, through substrate vias (TSVs), and/or the like) forming electrical connections between the bond sites 326. Further, as illustrated in FIG. 3A, the bond sites 326 and/or metallization layers 328 can have a variety of sizes and/or configurations. In various embodiments, the base interposer 320 can be a silicon interposer, a prepreg substrate, and/or the like, with the metallization structures formed therein. In some embodiments, the base interposer 320 is an embedded trace substrate (ETS), allowing the metallization structures to be formed with a relatively fine pitch (e.g., in close proximity).

Similarly, the wire bond bridge 330 (sometimes also referred to herein as a “wire bond interposer,” a “bridge component,” and/or the like) includes a landing surface 332 (sometimes also referred to herein as a “wire bonding surface,” an “uppermost surface,” and/or the like) and a bonding surface 334 (sometimes also referred to herein as a “lower surface,” a “packaging surface,” and/or the like) opposite the landing surface 332 (and facing the upper surface 322 of the base interposer 320). Further, the wire bond bridge 330 includes a plurality of metallization structures providing electrical connections through the wire bond bridge 330. For example, the wire bond bridge 330 includes bond sites 336 (sometimes also referred to herein as “bridge bond sites”), one or more TSVs 337 extending through the wire bond bridge 330, and one or more redistribution layers 338. The metallization structures allow the wire bond bridge to have a first height H₁ and/or allow the bridge package 310 to have a second height H₂. As discussed in more detail below, the height of the wire bond bridge 330 (and the bridge package 310 overall) allows the bridge package 310 to help reduce a length of wire bonds in a stacked semiconductor device.

As further illustrated in FIG. 3A, the wire bond bridge 330 is integrated with the upper surface 322 of the base interposer 320 via one or more first conductive structures 342. The first conductive structures 342 can include solder structures (e.g., solder balls, micro bumps, and/or the like), conductive pillars, metal-metal bonds, and/or the like. Similarly, the controller 312 (e.g., a controller die) is integrated with the lower surface 324 of the base interposer 320 via one or more second conductive structures 344 (e.g., solder structures (e.g., solder balls, micro bumps, and/or the like), conductive pillars, metal-metal bonds, and/or the like). Accordingly, for example, the base interposer 320 can (e.g., via the metallization layers 328) electrically/communicatively couple the controller 312 to the wire bond bridge 330. As a result, the bridge package 310 provides access to the controller 312 via the bond sites 336 at the landing surface 332 of the wire bond bridge 330. Further, the base interposer 320 can provide a plurality of electrical/communicative connections between the controller 312 and the bond sites 326 at the lower surface 324 of the base interposer 320. As a result, the bridge package 310 further provides access to the controller 312 via the bond sites 326 at the lower surface 324 of the base interposer 320.

Further, as discussed in more detail below, the base interposer 320 can provide three (or more) independent communication paths to the controller 312. Purely by way of example, a first communication path can be coupled to a first subset of the bond sites 326 at the lower surface 324 of the base interposer 320 to provide peripheral access to the controller (e.g., from a device outside of an associated stacked semiconductor device); a second communication path can be coupled to a second subset of the bond sites 326 at the lower surface 324 of the base interposer 320 to provide access to a first set of dies in the associated stacked semiconductor device; and a third communication path can be coupled to the bond sites 336 at the landing surface 332 of the wire bond bridge 330 (e.g., via the bond sites 326 at the upper surface 322 of the base interposer 320) to provide access to a second set of dies in the associated stacked semiconductor device. In some embodiments, each of the bond sites 326 on the base interposer 320 is electrically/communicatively coupled to the controller 312 via independent metallization layers 328 such that each of the bond sites 326 provides independent access to the controller 312. To help support the independent route lines, as further illustrated in FIG. 3A, the second conductive structures 344 can be relatively small structures (e.g., micro bumps, smaller than the first conductive structures 342), thereby providing a relatively high number of access points to the controller 312. Additionally, or alternatively, as discussed in more detail below, the metallization layers 328 in the base interposer 320 (and/or the redistribution layers 338 in the wire bond bridge 330) can include trace-matching paths to help establish equal path lengths between the controller 312 and individual dies the associated stacked semiconductor device.

FIG. 3B is a partially schematic cross-sectional view of a stacked semiconductor device 300 configured in accordance with embodiments of the present technology. As illustrated in FIG. 3B, the stacked semiconductor device 300 (“device 300,” sometimes also referred to herein as a “stacked semiconductor package”) includes a base substrate 350, as well as a bridge package 310 and one or more die stacks 360 (two illustrated in FIG. 3B) each integrated with (e.g., carried by and coupled to) an upper surface 352 of the base substrate 350. Further, the device 300 can include a mold material 380 (e.g., an epoxy-based encapsulant and/or any other suitable material) deposited over the upper surface 352, the bridge package 310, and the die stacks 360. The base substrate 350 can be a package substrate (e.g., printed circuit board, a prepreg substrate, and/or the like), a silicon interposer, and/or any other suitable substrate to integrate with the bridge package 310 and the die stacks 360.

In the illustrated embodiments, the bridge package 310 is generally similar to the bridge package 310 discussed above with reference to FIG. 3A. For example, the bridge package 310 includes a base interposer 320, as well as a controller 312 and a wire bond bridge 330 each integrated with the base interposer 320. The base interposer 320, in turn, is integrated with a central portion of the upper surface 352 of the base substrate 350 via a plurality of third conductive structures 346. Similar to the discussion above, the third conductive structures 346 can include solder structures (e.g., solder balls, micro bumps, and/or the like), conductive pillars, metal-metal bonds, and/or the like. In the illustrated embodiment, the third conductive structures 346 peripherally surround the controller 312 and are taller than the controller 312. As a result, the controller 312 is carried by the base interposer 320 above the upper surface 352 of the base substrate 350.

In the illustrated embodiment, the device 300 includes two die stacks 360 carried by peripheral portions of the upper surface 352 of the base substrate 350. The die stacks 360 are positioned on opposite sides of the bridge package 310. Further, each of the die stacks 360 includes a plurality of the individual dies 362 stacked into a first tier 364a and a second tier 364b. The individual dies 362 in the first tier 364a are each laterally offset from each other in a first direction (e.g., from a periphery of the device 300 toward a center of the device 300), and the individual dies 362 in the second tier 364b are each laterally offset from each other in a second direction opposite the first direction (e.g., from the center of the device 300 toward the periphery of the device 300). As a result, each of the die stacks 360 has a wing-shaped construction. Still further, the die stacks 360 are mirrored from each other, thereby providing an x-shaped wing construction for the die stacks 360 overall.

As further illustrated in FIG. 3B, each of the individual dies 362 in the first tier 364a are communicably/electrically coupled to substrate bond sites 356 at the upper surface 352 of the base substrate 350 via one or more first wire bonds 372. The substrate bond sites 356 (e.g., bond pads formed at the upper surface 352), in turn, are coupled to the bridge package 310 (and the controller 312 therein) via one or more metallization layers 358 (e.g., signal route lines) formed in the base substrate 350, thereby establishing first communication paths to each of the individual dies 362 in the first tier 364a. In contrast, each of the individual dies 362 in the second tier 364b are communicably/electrically coupled to bond sites 336 at a landing surface 332 of the wire bond bridge 330 in the bridge package 310 via one or more second wire bonds 374. As discussed above, the bond sites 336 at the landing surface 332 of the wire bond bridge 330 are coupled to the controller 312 via metallization structures (e.g., metallization layers, TSVs, and/or the like) in the wire bond bridge 330 and the base interposer 320. As a result, the base interposer 320, wire bond bridge 330, and the second wire bonds 374 establish second communication paths to each of the individual dies 362 in the second tier 364b.

The multi-tier design of the die stacks 360 can allow the die stacks 360 to increase in height (e.g., up to at least 32 dies per die stack). As a result, the device 300 can include more of the individual dies 362 in a given longitudinal footprint and/or can have an increased memory density within the given longitudinal footprint. Further, the wing-shaped design of the die stacks 360 can help stabilize the die stacks 360 by, for example, eliminating the overhanging portion 236 discussed above with reference to FIG. 2. As a result, each of the die stacks 360 can be more stable than the die stacks 230 discussed above with reference to FIG. 2. In turn, the die stacks 360 can be less likely to fail during manufacturing and/or can help improve an expected lifespan of the device 300 (e.g., by being less likely to fail under stress during operation). Further, the wing-shaped design of the die stacks 360 can help reduce the occurrence of wire sweep issues since the first wire bonds 372 and the second wire bonds 374 are formed in different locations. Still further, the bridge package 310 (e.g., via the wire bond bridge 330 and the base interposer 320) provides a solid device connection between the second wire bonds 374 and the controller 312, beginning at a third height H₃ above the base substrate 350. The solid connection provided by the bridge package 310 helps reduce the overall length of the second wire bonds 374, thereby further reducing the chance of wire sweep issues in the device 300. For example, in the illustrated embodiments, the landing surface 332 of the wire bond bridge 330 is coplanar with an upper surface of an uppermost individual die 362a in the first tier 364a of the die stacks 360. As a result, the landing surface 332 of the wire bond bridge 330 mimics the upper surface 352 of the base substrate 350 for the distance required for wire bonds. As a result, for example, each of the second wire bonds 374 can have a length generally equal to a corresponding one of the first wire bonds 372. In various other embodiments, the third height H₃ is set at various other heights (e.g., such that the landing surface 332 of the wire bond bridge 330 is below and/or above the uppermost individual die 362a in the first tier 364a). Additionally, or alternatively, the solid connection provided by the bridge package 310 can help improve the stability of the device 300 overall, further helping extend the expected lifespan of the device 300.

In some embodiments, the metallization layers 358 in the base substrate 350, the metallization layers 328 in the base interposer 320, and/or the redistribution layers 338 in the wire bond bridge 330 can be configured to match signal paths between various individual dies in the die stacks 360. For example, the metallization layers 358 in the metallization layers 328 in the base interposer 320, and/or the redistribution layers 338 in the wire bond bridge 330 can include one or more serpentine route lines to help ensure that a first communication path to a first individual die in the first tier 364a has a generally equal length as a second communication path to a second individual die in the second tier 364b. In some embodiments, the metallization layers 328 in the base interposer 320 and/or the redistribution layers 338 in the wire bond bridge 330 help match the path lengths for corresponding pairs of dies in the first and second tiers 364a, 364b.

In the embodiments illustrated in FIG. 3B, the x-wing shape of the die stacks 360 allows at least a portion of the bridge package 310 (e.g., a portion of the base interposer 320) to be positioned beneath at least a portion of the die stacks 360 (e.g., beneath a portion of the individual dies 362 in the first tier 364a). For example, an innermost edge 365 of the die stacks 360 can overhang (e.g., be vertically aligned with) a portion of the base interposer 320. Said another way, the base interposer 320 can be positioned at least partially within the longitudinal footprint of the die stacks 360. As a result, the x-wing shape of the die stacks 360 can help reduce a size of the device 300 required to provide a given level of semiconductor functioning (e.g., memory, processing capacity, and/or the like) and/or can help increase a density of the semiconductor functioning. In some embodiments, the controller 312 is also positioned at least partially within the longitudinal footprint of the die stacks 360, thereby further enabling size reductions and/or increases in density.

As further illustrated in FIG. 3B, the base substrate 350 can further include one or more metallization features 359 extending between the upper surface 352 (sometimes also referred to herein as the “active surface,” “frontside,” and/or the like) to a lower surface 354 (sometimes also referred to herein as the “backside,” “back surface,” and/or the like). The metallization features 359 can include metallization layers, route lines, TSVs, and/or any other suitable component. As a result, for example, the metallization features 359 can couple the bridge package 310 (and the controller 312 therein and/or any other suitable component) to one or more package connections 390 (e.g., solder structures, bond sites, conductive pillars, and/or the like) at the lower surface 354 of the base substrate 350. The package connections 390, in turn, can be coupled to various devices external to the device 300.

FIG. 4 is a flow diagram of a process 400 for manufacturing a stacked semiconductor device in accordance with embodiments of the present technology. The process 400 can be implemented by a single manufacturing apparatus and/or split between multiple manufacturing apparatuses to stacked semiconductor devices with wing-shaped die stacks and/or elevated interposers.

The process 400 begins at block 402 by integrating a bridge package (e.g., the bridge package 310 of FIGS. 3A and 3B) with a base substrate (e.g., the base substrate 350 of FIG. 3B) for the stacked semiconductor device. Integrating the bridge package can include stacking the bridge package on the base substrate and forming electrical and/or physical connections between the bridge package and the base substrate. Forming the connections can include a reflow process for one or more solder structures, an annealing process to form metal-metal connections and/or substrate-substrate connections, and/or any other suitable bonding process. In some embodiments, the process 400 at block 402 integrates a pre-constructed bridge package with the base substrate. In some embodiments, the process 400 at block 402 includes one or more sub-processes to form the bridge package.

For example, in the embodiments illustrated in FIG. 4, the process 400 at block 402 can include blocks 404–408. At block 404, the process 400 includes integrating a controller (e.g., the controller 312 of FIGS. 3A and 3B) with an RDL interposer (e.g., the base interposer 320 of FIGS. 3A and 3B). Similar to the discussion above, the integration process can include stacking the controller on the RDL interposer (or vice versa) and forming electrical and/or physical connections between the controller and the RDL interposer. Forming the connections can include a reflow process for one or more solder structures, an annealing process to form metal-metal connections and/or substrate-substrate connections, and/or any other suitable bonding process.

At block 406, the process 400 includes integrating a bridge interposer (e.g., the wire bond bridge 330 of FIGS. 3A and 3B) with the RDL interposer. Similar to the discussion above, the integration process can include stacking the bridge interposer on the RDL interposer (or vice versa) and forming electrical and/or physical connections between the bridge interposer and the RDL interposer. Further, forming the connections can include a reflow process for one or more solder structures, an annealing process to form metal-metal connections and/or substrate-substrate connections, and/or any other suitable bonding process.

At block 408, the process 400 includes integrating the RDL interposer with the base substrate. As discussed above, the integration process can include stacking the bridge package (e.g., the RDL interposer, the controller, and the bridge interposer) on the base substrate and then forming electrical and/or physical connections between the RDL interposer and the base substrate.

At block 410, the process 400 includes the process 400 includes stacking a first portion of one or more die wings (e.g., the first tier 364a of the die stacks 360 of FIG. 3B) on the base substrate adjacent to the bridge package. In some embodiments, the stacking process includes stacking dies individually (e.g., one by one) and/or in subsets of the first portion. For each of the die wings, the dies are staggered in a first direction as they are stacked (and/or are pre-staggered in the first direction when stacked in subsets and/or altogether). In some embodiments, the upper dies in the first portion of the die wings overhang a portion of the bridge package (e.g., the RDL interposer and/or the controller) as they are stacked. At block 412, the process 400 includes forming first wire bonds between each of the dies in the first portion of the die wings and the base substrate. As a result, each of the dies in the first portion is carried by and electrically/communicably coupled to the base substrate. As discussed above, the base substrate, in turn, electrically couples the dies in the first portion of the die wings to the RDL substrate in the bridge package (e.g., via the metallization layers 358 of FIG. 3B). Further, the RDL substrate couples the dies in the first portion of the die wings to the controller in the bridge package (e.g., via the metallization layers 328 of FIG. 3A).

At block 414, the process 400 includes stacking a second portion of the die wings (e.g., the second tier 364b of the die stacks 360 of FIG. 3B) on the base substrate on top of the first portion. In some embodiments, the stacking process includes stacking dies individually (e.g., one by one) and/or in subsets of the second portion. For each of the die wings, the dies in the second portion are staggered in a second direction that is opposite to the first direction as they are stacked. As a result, each of the die wings can have a balanced wing shape once complete. At block 416, the process 400 includes forming second wire bonds between each of the dies in the second portion of the die wings and the bridge interposer. As discussed above with reference to FIGS. 3A and 3B, the bridge interposer electrically couples the dies in the second portion of the die wings to the RDL interposer (e.g., via the TSVs 337 and/or the redistribution layers 338 of FIG. 3A). The RDL interposer, in turn, electrically couples the dies in the second portion of the die wings to the controller (e.g., via the metallization layers 328 of FIG. 3A).

At block 418, the process 400 includes depositing a mold compound over the base substrate to cover the bridge package (and each of the components therein) and each of the die wings. The mold compound can include an epoxy-based resin and/or any other suitable material to protect and/or insulate the components of the stacked semiconductor device.

Although blocks 402–418 are illustrated and discussed with reference to FIG. 4 in a particular order, one of skill in the art will understand that the technology disclosed herein is not so limited. Purely by way of example, the first and second portions of the die wings can each be stacked on the base substrate before forming any wire bonds (e.g., by executing blocks 410 and 414 generally simultaneously). Indeed, in some embodiments, each of the die wings includes a pre-packaged stack of dies for the first and second portions of the die wings. In a related example, the bridge package can be a pre-packaged device and integrated with the base substrate in a single process (e.g., such that block 402 includes only block 408 to integrate the RDL interposer with the base substrate). Additionally, or alternatively, it will be understood that the process 400 can include various additional steps and/or sub-processes and/or omit various steps and/or processes. Purely by way of example, the process 400 can include integrating various other electrical components (e.g., capacitors) with the base substrate before depositing the mold compound at block 418. Still further, it will be understood that the process 400 can be modified to integrate the bridge package with various other substrates to provide electrical connections to devices with various other die stack configurations and/or to provide electrical connections to various other devices.

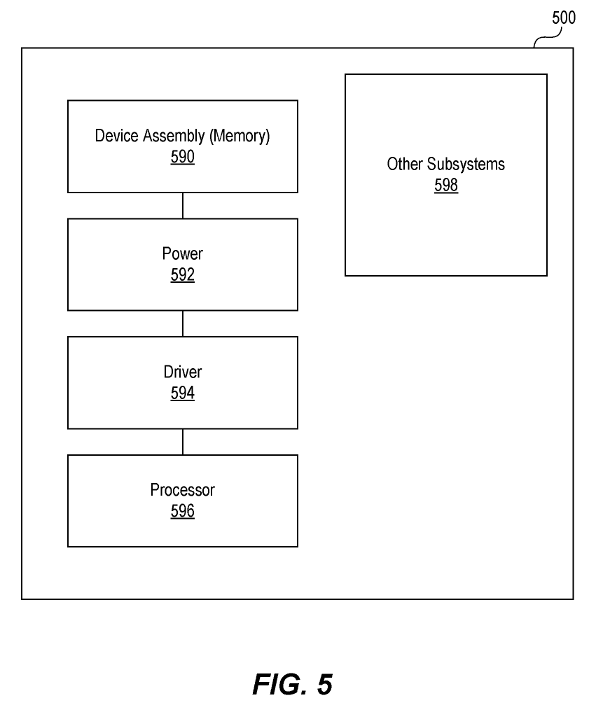

FIG. 5 is a schematic view of a system 500 that includes a semiconductor package configured in accordance with embodiments of the present technology. That is, the semiconductor packages discussed above can be incorporated into any of a myriad of larger and/or more complex systems, a representative example of which is system 500, shown schematically in FIG. 5. The system 500 can include a memory 590 (e.g., SRAM, DRAM, flash, and/or other memory devices), a power supply 592, a drive 594, a processor 596, and/or other subsystems or components 598. Semiconductor packages of the type discussed above with reference to FIGS. 3A and 3B and/or manufactured using processes of the type discussed above with reference to FIG. 4 can be included in any of the elements shown in FIG. 5. Purely by way of example, the stacked semiconductor device 300 of FIG. 3B can be deployed in the memory 590 (e.g., in a managed NAND for us in various consumer electronics, automotive electronics, and the like; an SSD package; and/or any other suitable memory device).

The resulting system 500 can be configured to perform any of a wide variety of suitable computing, processing, storage, sensing, imaging, and/or other functions. Accordingly, representative examples of the system 500 include, without limitation, computers and/or other data processors, such as desktop computers, laptop computers, Internet appliances, hand-held devices (e.g., palm-top computers, wearable computers, cellular or mobile phones, automotive electronics, personal digital assistants, music players, etc.), tablets, multi-processor systems, processor-based or programmable consumer electronics, network computers, and minicomputers. Additional representative examples of the system 500 include lights, cameras, vehicles, etc. With regard to these and other examples, the system 500 can be housed in a single unit or distributed over multiple interconnected units, e.g., through a communication network. The components of the system 500 can accordingly include local and/or remote memory storage devices and any of a wide variety of suitable computer-readable media.

From the foregoing, it will be appreciated that specific embodiments of the technology have been described herein for purposes of illustration, but well-known structures and functions have not been shown or described in detail to avoid unnecessarily obscuring the description of the embodiments of the technology. To the extent any material incorporated herein by reference conflicts with the present disclosure, the present disclosure controls. Where the context permits, singular or plural terms may also include the plural or singular term, respectively. Moreover, unless the word “or” is expressly limited to mean only a single item exclusive from the other items in reference to a list of two or more items, then the use of “or” in such a list is to be interpreted as including (a) any single item in the list, (b) all of the items in the list, or (c) any combination of the items in the list. Furthermore, as used herein, the phrase “and/or” as in “A and/or B” refers to A alone, B alone, and both A and B. Additionally, the terms “comprising,” “including,” “having,” and “with” are used throughout to mean including at least the recited feature(s) such that any greater number of the same features and/or additional types of other features are not precluded. Further, the terms “generally, “approximately,” and “about” are used herein to mean within at least within 10% of a given value or limit. Purely by way of example, an approximate ratio means within 10% of the given ratio.

Several implementations of the disclosed technology are described above in reference to the figures. The computing devices on which the described technology may be implemented can include one or more central processing units, memory, input devices (e.g., keyboard and pointing devices), output devices (e.g., display devices), storage devices (e.g., disk drives), and network devices (e.g., network interfaces). The memory and storage devices are computer-readable storage media that can store instructions that implement at least portions of the described technology. In addition, the data structures and message structures can be stored or transmitted via a data transmission medium, such as a signal on a communications link. Various communications links can be used, such as the Internet, a local area network, a wide area network, or a point-to-point dial-up connection. Thus, computer-readable media can comprise computer-readable storage media (e.g., “non-transitory” media) and computer-readable transmission media.

From the foregoing, it will also be appreciated that various modifications may be made without deviating from the disclosure or the technology. For example, one of ordinary skill in the art will understand that various components of the technology can be further divided into subcomponents, or that various components and functions of the technology may be combined and integrated. In addition, certain aspects of the technology described in the context of particular embodiments may also be combined or eliminated in other embodiments.

Furthermore, although advantages associated with certain embodiments of the technology have been described in the context of those embodiments, other embodiments may also exhibit such advantages, and not all embodiments need necessarily exhibit such advantages to fall within the scope of the technology. Accordingly, the disclosure and associated technology can encompass other embodiments not expressly shown or described herein.

We claim:

1. A stacked semiconductor device, comprising:
a base substrate;
a bridge package integrated with an active surface of the base substrate, the bridge package comprising:
a base interposer;
a controller integrated with a lower surface of the base interposer; and
a wire bond bridge, wherein:
the wire bond bridge comprises a landing surface having a plurality of first bond sites, a bonding surface opposite the landing surface and having a plurality of second bond sites, and a plurality of interconnects electrically coupled between corresponding bond site pairs from the plurality of first bond sites and the plurality of second bond sites, and
each of the plurality of second bond sites is electrically coupled to an interposer bond site at an upper surface of the base interposer; and
a plurality of dies carried by the active surface of the base substrate adjacent to the bridge package, wherein the plurality of dies comprises:
a first tier that includes a plurality of first dies staggered in a first direction, wherein each of the plurality of first dies is electrically coupled to the active surface via one or more first wire bonds; and
a second tier carried by the first tier that includes a plurality of second dies staggered in a second direction opposite the first direction, wherein each of the plurality of second dies is electrically coupled to the plurality of second bond sites at the landing surface of the wire bond bridge via one or more second wire bonds.

2. The stacked semiconductor device of claim 1 wherein:
the plurality of first dies are coupled to the controller via a first communication path comprising the base interposer, the base substrate, and the one or more first wire bonds, wherein the first communication path has a first signal path length;
the plurality of second dies are coupled to the controller via a second communication path comprising the base interposer, the wire bond bridge, and the one or more second wire bonds, wherein the second communication path has a second signal path length; and
the base interposer comprises a plurality of metallization layers forming route lines between the upper surface and the lower surface, wherein the route lines are configured to match the second signal path length the first signal path length.

3. The stacked semiconductor device of claim 1 wherein an innermost edge of the plurality of dies is vertically aligned with the base interposer.

4. The stacked semiconductor device of claim 1 wherein the landing surface is coplanar with a top surface of the first tier from the plurality of dies.

5. The stacked semiconductor device of claim 1 wherein the base interposer comprises an embedded trace substrate having a plurality of first traces coupled between the controller and the base substrate and a plurality of second traces coupled between the controller and the plurality of dies.

6. The stacked semiconductor device of claim 1 wherein the plurality of dies form a first die stack on the base substrate, wherein the first die stack is carried by the active surface of the base substrate adjacent to a first side of the bridge package, and wherein the stacked semiconductor device further comprises a second die stack carried by the active surface of the base substrate adjacent to a second side of the bridge package opposite the first side.

7. The stacked semiconductor device of claim 6 wherein the second die stack comprises:
a third tier that includes a plurality of third dies staggered in the second direction, wherein each of the plurality of third dies is electrically coupled to the plurality of first bond sites at the active surface via one or more third wire bonds; and
a fourth tier carried by the third tier that includes a plurality of fourth dies staggered in the first direction, wherein each of the plurality of fourth dies is electrically coupled to the plurality of second bond sites at the landing surface of the wire bond bridge via one or more fourth wire bonds.

8. The stacked semiconductor device of claim 1 wherein the base interposer of the bridge package is integrated with the base substrate via a plurality of conductive structures extending between the lower surface of the base interposer and the active surface of the base substrate, wherein the plurality of conductive structures are positioned peripheral to the controller.

9. A bridge package for use with a stacked semiconductor device, the bridge package comprising:
a redistribution interposer substrate having an upper surface and a lower surface opposite the upper surface;
a controller die integrated with the lower surface of the redistribution interposer substrate; and
a bridge interposer integrated with the upper surface of the redistribution interposer substrate, the bridge interposer comprising:
a bonding surface facing the upper surface of the redistribution interposer substrate, the bonding surface including a plurality of first bond sites;
a landing surface opposite the bonding surface, the landing surface including a plurality of second bond sites; and
a plurality of interconnects formed in the bridge interposer, each of the plurality of interconnects electrically coupling a corresponding pair of bond sites from the plurality of first bond sites and the plurality of second bond sites.

10. The bridge package of claim 9 wherein the controller die is integrated with a plurality of first interposer bond sites at the lower surface of the redistribution interposer substrate, and wherein the lower surface of the redistribution interposer substrate includes a plurality of second interposer bond sites peripherally surrounding the plurality of first interposer bond sites.

11. The bridge package of claim 9 wherein the redistribution interposer substrate comprises a plurality of metallization layers, the plurality of metallization layers comprising:
a plurality of first route lines coupled between the controller die and a plurality of first interposer bond sites at the lower surface of the redistribution interposer substrate; and
a plurality of second route lines coupled between the controller die and a plurality of second interposer bond sites at the upper surface of the redistribution interposer substrate.

12. The bridge package of claim 11 wherein the plurality of metallization layers further comprises a plurality of third route lines coupled between the controller die and a plurality of third interposer bond sites at the lower surface of the redistribution interposer substrate.

13. The bridge package of claim 9 wherein the redistribution interposer substrate comprises a plurality of metallization layers, the plurality of metallization layers comprising a plurality of route lines positioned to match a first length of a first signal path in the stacked semiconductor device to a second length of a second signal path in the stacked semiconductor device.

14. The bridge package of claim 9 wherein each first bond site from the plurality of first bond sites at the bonding surface is electrically coupled to an interposer bond site at the upper surface of the redistribution interposer substrate.

15. The bridge package of claim 14 wherein each of the interposer bond sites is electrically coupled to the controller die via one or more independent metallization layers formed in the redistribution interposer substrate such that each of the interposer bond sites provides independent access to the controller die.

16. The bridge package of claim 9 wherein the bridge interposer is integrated with the upper surface of the redistribution interposer substrate via first conductive structures, and wherein the controller die is integrated with the lower surface of the redistribution interposer substrate via second conductive structures smaller than the first conductive structures.

17. A method for manufacturing a stacked semiconductor device, the method comprising:
forming a bridge package comprising a redistribution layer (RDL) interposer, a controller integrated with a first surface of the RDL interposer, and a bridge interposer integrated with a second surface of the RDL interposer;
integrating the bridge package with an active surface of a base substrate of the stacked semiconductor device; and
for each individual die wing of one or more die wings:
stacking a first portion of the individual die wing on the active surface of the base substrate adjacent to the bridge package ;
forming first wire bonds between the first portion and one or more first bond pads on the active surface of the base substrate;
stacking a second portion of the individual die wing on the first portion of the individual die wing; and
forming second wire bonds between the second portion and one or more second bond pads on an upper surface of the bridge interposer.

18. The method of claim 17 wherein forming the bridge package comprises:
integrating the controller with the first surface of the RDL interposer via a first reflow process; and
integrating the bridge interposer with the second surface of the RDL interposer via a second reflow process.

19. The method of claim 17 wherein, for each of the one or more die wings:
stacking the first portion of the one or more die wings on the active surface of the base substrate adjacent comprises staggering each die in the first portion in a first direction; and
stacking the second portion of the one or more die wings on the first portion of the one or more die wings comprises staggering each die in the second portion in a second direction opposite the first direction.

20. The method of claim 17 wherein, for each of the one or more die wings, stacking the first portion of the one or more die wings on the active surface of the base substrate comprises at stacking dies to a height coplanar with an uppermost surface of the bridge package.
